(19) United States
(12) Patent Application Publication
(10) Pub. No.: US 2026/0024576 A1
(43) Pub. Date: Jan. 22, 2026

(54) MULTIPLEXOR PLACEMENT FOR IMPLEMENTING A PROCESSING UNIT IN MEMORY

(71) Applicant: Micron Technology, Inc., Boise, ID (US)

(72) Inventors: Glen E. Hush, Boise, ID (US); Peter L. Brown, Eagle, ID (US)

(21) Appl. No.: 19/269,166

(22) Filed: Jul. 15, 2025

Related U.S. Application Data
(60) Provisional application No. 63/672,124, filed on Jul. 16, 2024.

(51) Int. Cl. G11C 11/4093; G06F 7/544; G11C 11/4076; G11C 11/4096; G11C 29/52

(52) U.S. Cl. CPC G11C 11/4093; G06F 7/5443; G11C 11/4076; G11C 11/4096; G11C 29/52

(57) ABSTRACT

A memory device can include a first error correction code (ECC) circuitry, a second ECC circuitry, and a multiplexor (MUX). The first ECC circuitry receive first data from a first bank. The second ECC circuitry can receive second data from a second bank. A MUX can receive the first data from the first ECC circuitry and the second data from the second ECC circuitry. The MUX can provide the first data in a first portion of a duration of time. The MUX can provide the second data in a second portion of the duration of time. A processing unit (PU) can perform a first plurality of multiplication operations utilizing the first data provided by the MUX during the first portion of the duration of time and a second plurality of multiplication operations utilizing the second data provided by the MUX during the second portion of the duration of time.

### PRIORITY INFORMATION

This application claims the benefit of U.S. Provisional Application No. 63/672,124, filed on Jul. 16, 2024, the contents of which are incorporated herein by reference.

### TECHNICAL FIELD

The present disclosure relates generally to memory, and more particularly to multiplexor placement for implementing a processing unit in memory.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored data when not powered and can include NAND flash memory, NOR flash memory, read only memory (ROM), Electrically Erasable Programmable ROM (EEPROM), Erasable Programmable ROM (EPROM), and resistance variable memory such as phase change random access memory (PCRAM), resistive random access memory (RRAM), and magnetoresistive random access memory (MRAM), among others.

Memory is also utilized as volatile and non-volatile data storage for a wide range of electronic applications. Non-volatile memory may be used in, for example, personal computers, portable memory sticks, digital cameras, cellular telephones, portable music players such as MP3 players, movie players, and other electronic devices. Memory cells can be arranged into arrays, with the arrays being used in memory devices.

### BRIEF DESCRIPTION OF THE DRAWINGS

FIG. 1 is a block diagram of an apparatus in the form of a computing system including a memory device in accordance with a number of embodiments of the present disclosure.

FIG. 2 is a block diagram of a memory device including a plurality of banks of memory cells in accordance with a number of embodiments of the present disclosure.

FIG. 3 is a block diagram of a processing unit including a multiplexor in accordance with a number of embodiments of the present disclosure.

FIG. 4 is a block diagram of a processing unit including a multiplexor in accordance with a number of embodiments of the present disclosure.

FIG. 5 is a block diagram of a memory device including a multiplexor coupled to multiple error correction code circuitries and a processing unit in accordance with a number of embodiments of the present disclosure.

FIG. 6 is a block diagram of a memory device including a multiplexor coupled to multiple data sense amplifiers and an error correction code circuitry in accordance with a number of embodiments of the present disclosure.

FIG. 7 illustrates an example flow diagram of a method for implementing a multiplexor in a processing unit of memory in accordance with a number of embodiments of the present disclosure.

FIG. 8 illustrates an example machine of a computer system within which a set of instructions, for causing the machine to perform any one or more of the methodologies discussed herein, can be executed.

### DETAILED DESCRIPTION

The present disclosure describes multiplexor placement for implementing a processing unit in memory. In various examples, a multiplexor (MUX) can be placed strategically between data sense amplifiers (DSA) and a processing unit (PU) to allow for the die size reduction of the PU.

In some previous approaches, a PU can include a plurality of multiply-accumulate (MAC) units. The plurality of MAC units can receive a plurality of data values. A PU may be implemented using a set quantity of MAC units. For example, the PU may traditionally be implemented using thirty-two MAC units. Each of the MAC units can include an accumulator register that stores thirty-two data values (e.g., bits). Each of the thirty-two MAC units can receive eight bits of data every time data is sensed (e.g., read) from a memory array (e.g., a bank of memory). The read latency can be 5 nanoseconds (ns). Each of the thirty-two MAC units can receive eight bits of data every 5 ns. Each of the eight bits of data can represent a different data value. Each of the thirty-two MAC units can receive a data value every time data is sensed. For example, each of the thirty-two MAC units can receive a data value every 5 ns. A separate PU unit can be implemented for each bank of a memory device. For example, a first bank can be coupled to a first PU and a second bank can be coupled to a second PU.

However, the MAC units may perform MAC operations in less time than the read latency. For example, the MAC units may perform a plurality of operations utilizing the received eight bits of data in less time than the 5 ns read latency. As such, the MAC units, or portions of the MAC units, may be underutilized because the MAC units or portion of the MAC units remain inactive for the remaining portion of the 5 ns. Implementing a PU per bank of the memory device can also utilize more die space than is needed if the PUs are not being fully utilized.

In order to address these and other deficiencies of previous approaches, embodiments of the present disclosure implement a PU that provides data (e.g., data values) to the MAC units such that the MAC units are continually utilized. For example, a single PU can be implemented per pair of banks of a memory device. The single PU can be coupled to the multiple banks of the memory device using a MUX. The placement of the MUX between the PU and the multiple banks can be used to reduce the quantity of DSAs and/or error correction code (ECC) circuitry. Reducing the quantity of DSAs and/or ECC circuitry can reduce the cost of implementing the memory device, can reduce power usage, and/or can reduce die size.

As used herein, a PU can include hardware and/or firmware to perform a plurality of operations. The PU can include MAC units which include hardware and/or firmware for performing a plurality of multiplication operations and a plurality of accumulation operations referred to as MAC operations.

For example, in embodiments of the present disclosure, a MUX can be implemented to provide data values to the PU. The MUX can provide portions of the data values in less time than the read latency. As used herein, the read latency refers to an interval of time starting when first data is sensed from the memory array and ending when second data is sensed from the array. For example, the MUX can provide a first portion and a second portion of the data values during the read latency such that the MAC units are utilized for the entirety of the read latency.

Given that the MAC units remain utilized for the read latency, fewer MAC units can be utilized than are utilized if the MAC units are only partially utilized during the read latency (e.g., as with previous approaches). For example, if thirty-two MAC units are partially utilized during a read latency (e.g., as with previous approaches), then only sixteen MAC units can be fully utilized for the same duration of time with the use of a MUX to continuously provide data to the sixteen MAC units in accordance with embodiments of the present disclosure. As used herein, a MUX can continuously provide data if the MUX provides data multiple times over a particular duration of time. For example, a MUX can continuously provide data values during a read latency if the MUX provides both first data and second data during the read latency, where the first data and the second data are provided separately.

The PU can be used to implement an artificial neural network (ANN) using the MAC units, for example. As used herein, ANNs can provide learning by forming probability weight associations between an input and an output. The probability weight associations can be provided by a plurality of nodes that comprise the ANN. The nodes together with weights, biases, and activation functions can be used to generate an output of the ANN based on the input to the ANN. A plurality of nodes of the ANN can be grouped to form layers of the ANN.

As used herein, artificial intelligence (AI) refers to the ability to improve an apparatus through “learning” such as by storing patterns and/or examples which can be utilized to take actions at a later time. Deep learning refers to a device's ability to learn from data provided as examples. Deep learning can be a subset of AI. Neural networks, among other types of networks, can be classified as deep learning. Improving the efficiency at which ANNs are executed can improve a function of a memory device executing the ANN and the function of the device in which the memory device is implemented. For example, improving the latency, power consumption, and/or throughput of the memory device implementing the ANN can cause an improvement to the latency, power consumption, and/or throughput of a memory device.

As used herein, “a number of” something can refer to one or more of such things. For example, a number of memory devices can refer to one or more memory devices. A “plurality” of something intends two or more. Additionally, designators such as “N,” as used herein, particularly with respect to reference numerals in the drawings, indicates that a number of the particular feature so designated can be included with a number of embodiments of the present disclosure.

The figures herein follow a numbering convention in which the first digit or digits correspond to the drawing figure number and the remaining digits identify an element or component in the drawing. Similar elements or components between different figures may be identified by the use of similar digits. As will be appreciated, elements shown in the various embodiments herein can be added, exchanged, and/or eliminated so as to provide a number of additional embodiments of the present disclosure. In addition, the proportion and the relative scale of the elements provided in the figures are intended to illustrate various embodiments of the present disclosure and are not to be used in a limiting sense.

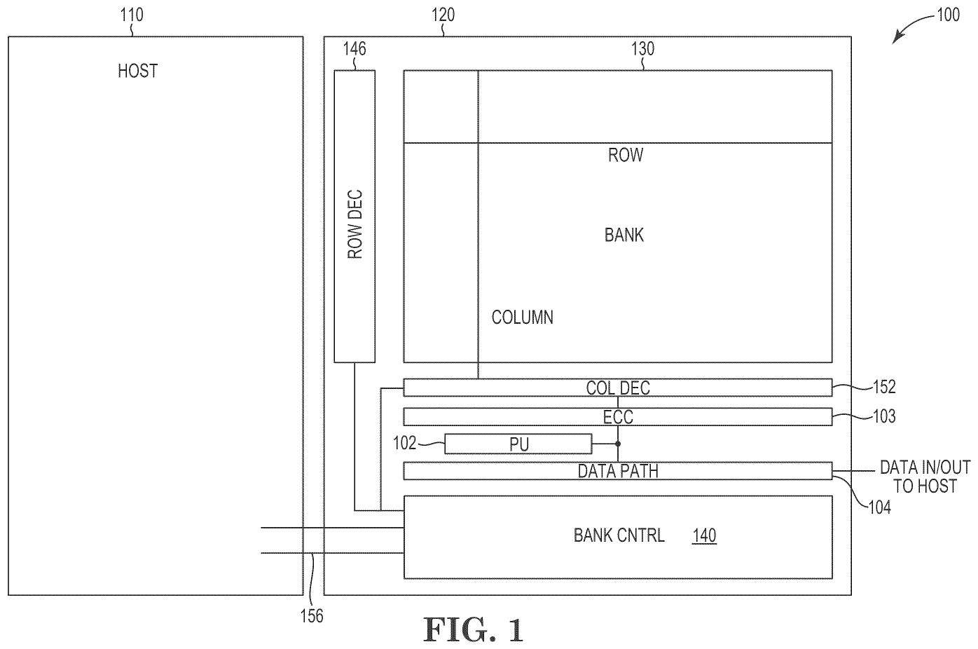

FIG. 1 is a block diagram of an apparatus in the form of a computing system 100 including a memory device 120 in accordance with a number of embodiments of the present disclosure. As used herein, a memory device 120, a bank 130 of memory cells, also referred to as a memory array 130, a host 110, and/or the PU might also be separately considered an “apparatus.”

In this example, system 100 includes a host 110 coupled to memory device 120 via an interface 156. The computing system 100 can be a personal laptop computer, a desktop computer, a digital camera, a mobile telephone, a memory card reader, or an Internet-of-Things (IoT) enabled device, among various other types of systems. Host 110 can include a number of processing resources (e.g., one or more processors, microprocessors, or some other type of controlling circuitry) capable of accessing memory 120. The system 100 can include separate integrated circuits, or both the host 110 and the memory device 120 can be on the same integrated circuit. For example, the host 110 may be a system controller of a memory system comprising multiple memory devices 120, with the system controller 110 providing access to the respective memory devices 120 by another processing resource such as a central processing unit (CPU).

In the example shown in FIG. 1, the host 110 is responsible for executing an operating system (OS) and/or various applications that can be loaded thereto (e.g., from memory device 120 via controller 140). The host 110 can provide access commands and/or security mode initialization commands to a memory device via the interface 156.

For clarity, the system 100 has been simplified to focus on features with particular relevance to the present disclosure. The memory array 130 can be a DRAM array, SRAM array, STT RAM array, PCRAM array, TRAM array, RRAM array, NAND flash array, and/or NOR flash array, for instance. The array 130 can comprise memory cells arranged in rows coupled by access lines (which may be referred to herein as word lines or select lines) and columns coupled by sense lines (which may be referred to herein as digit lines or data lines). Although a single array 130 is shown in FIG. 1, embodiments are not so limited. For instance, memory device 120 may include a number of arrays 130 (e.g., a number of banks 130 of DRAM cells).

The memory device 120 includes address circuitry to latch address signals provided over the interface 156. The interface 156 can include, for example, a physical interface employing a suitable protocol (e.g., a data bus, an address bus, and a command bus, or a combined data/address/command bus). Such protocol may be custom or proprietary, or the interface 156 may employ a standardized protocol, such as Peripheral Component Interconnect Express (PCIe), Gen-Z, CCIX, or the like. Address signals are received and decoded by a row decoder 146 and a column decoder 152 to access the memory array 130. Data can be read from memory array 130 by sensing voltage and/or current changes on the sense lines using sensing circuitry. The sensing circuitry can comprise, for example, sense amplifiers that can read and latch a page (e.g., row) of data from the memory array 130. The I/O circuitry can be used for bi-directional data communication with host 110 over the interface 156. Read/write circuitry is used to write data to the memory array 130 or read data from the memory array 130.

Controller 140 decodes signals provided by the host 110. These signals can include chip enable signals, write enable signals, and address latch signals that are used to control operations performed on the memory array 130, including data read, data write, and data erase operations. In various embodiments, the controller 140 is responsible for executing instructions from the host 110. The controller 140 can comprise a state machine, a sequencer, and/or some other type of control circuitry, which may be implemented in the form of hardware, firmware, or software, or any combination of the three.

In various instances, the controller 140 can receive signals provided by the host 110 including signals requesting operations to be performed by the PU 102. As used herein, the PU 102 can include hardware, firmware, and/or software for performing operations, such as, for example, multiplication operations, using data provided by the memory array 130 and/or the host 110.

In various examples, error correction code (ECC) circuitry 103 can be coupled to the column decoder 152. The ECC circuitry 103 can receive data from the memory array 130 (e.g., the sensing circuitry of the memory array). The ECC circuitry 103 can perform error correction operations to correct errors in data sensed from the memory array 130. The PU 102 can be coupled to the ECC circuitry 102. The PU 102 can perform a plurality of operations on data received from the ECC circuitry 102. The PU 102 can provide an output to the data path 104. The data path 104 can provide data to the interface 156. In various instances, the data path 104 can include Input/Output (I/O lines) and/or receivers and/or drivers. As used herein, receivers can include circuitry configured to receive a signal. Drivers can describe circuitry to drive a signal across a line or a plurality of lines.

The PU 102 can include multiple MAC units. The MAC units can perform operations (e.g., multiplication operations) to implement an ANN. The PU 102 can also include a MUX that receives data values from (e.g., sensed from) memory array 130 (e.g., data that has been corrected by the ECC circuitry 102). Although the MUX is described as being part of the PU 102, the MUX can also be external to the PU 102. In various examples, the MUX can be implemented upstream from the PU 102 (e.g., between the PU and the memory array).

The MUX can provide data values received at the same time continuously to the MAC units. For example, the MUX can receive a plurality of data values (e.g., represented using a quantity of bits) during a duration of time (e.g., during a time period). The MUX can provide a first portion of the data values followed by a second portion of the data values to the MAC units within the time period. Implementing a MUX in a PU to provide data to the MAC units allows for less MAC units to be utilized than implementing the PU without a MUX. Although the implementations described herein utilize a MUX, the examples described herein can be extended to include different circuitry that can receive data, divide the data, and provide the divided data continuously over a period of time. For example, registers can be utilized instead of a MUX to perform the functions of a MUX. Although the examples provided herein are given in the context of data values, the examples described herein can be extended to include bits. For example, the MUX can provide a first portion and a second portion of a plurality of bits that represent data values to MAC units during a time period.

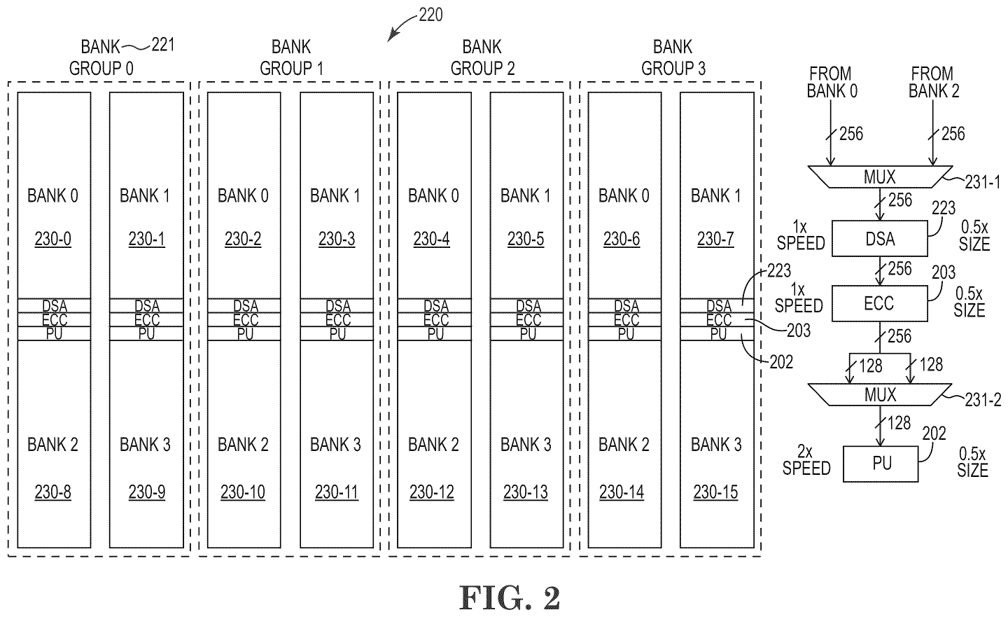

FIG. 2 is a block diagram of a memory device 220 having a plurality of banks of memory cells in accordance with a number of embodiments of the present disclosure. The banks 230-0, 230-1, 230-2, 230-3, 230-4, 230-5, 230-6, 230-7, 230-8, 230-9, 230-10, 230-11, 230-12, 230-13, 230-14, 230-15 can be referred to collectively as banks 230. The banks 230 can be analogous to bank 130 previously described in connection with FIG. 1. Further, although 16 banks are shown in the example illustrated in FIGS. 2, 5, and 6, embodiments of the present disclosure are not limited to a particular number of banks.

The banks 230 can be grouped into bank groups 221. For example, the banks 230-0, 230-1, 230-8, 230-9 can be grouped into a first bank group (e.g., bank group 0). The banks 230-2, 230-3, 230-10, 230-11 can be grouped into a second bank group (e.g., bank group 1). The banks 230-4, 230-5, 230-12, 230-13 can be grouped into a third bank group (e.g., bank group 2). The banks 230-6, 230-7, 230-14, 230-15 can be grouped into a fourth bank group (e.g., bank group 3).

The banks of each respective bank group can be organized into pairs that share at least a PU 202. For example, the banks 230-0, 230-8 of bank group 0 share a first PU (e.g., the PU 202). The banks 230-1, 230-9 of bank group 0 share a second PU. The banks 230-2, 230-10 of bank group 1 share a third PU. The banks 230-3, 230-11 of bank group 1 share a fourth PU. The banks 230-4, 230-12 of bank group 2 share a fifth PU. The banks 230-5, 230-13 of bank group 2 share a sixth PU. The banks 230-6, 230-14 of bank group 3 share a seventh PU. The banks 230-7, 230-15 of bank group 3 share an eighth PU.

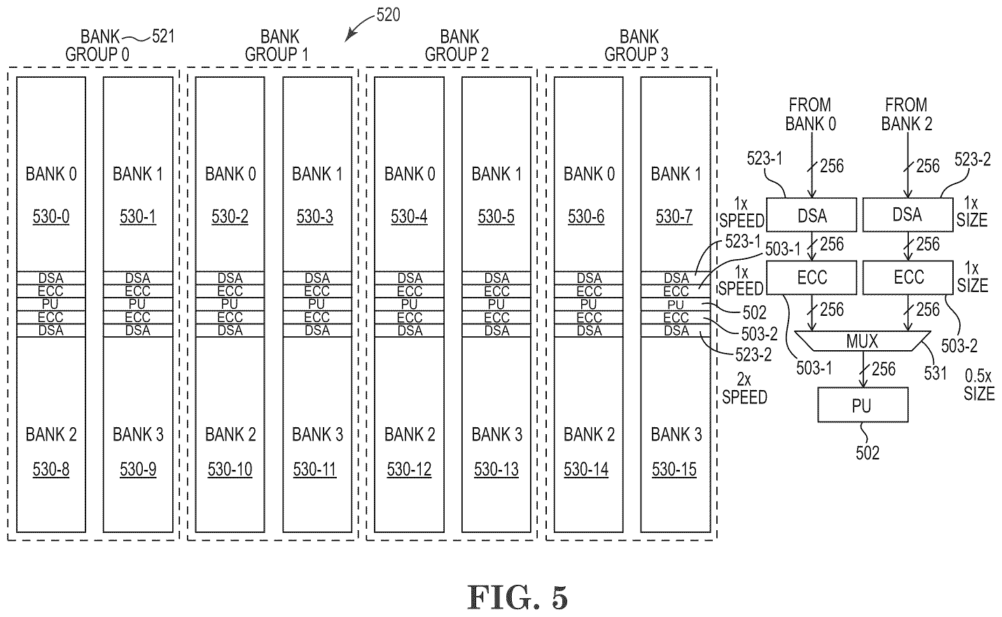

The example of FIG. 2 also shows the bank pairs sharing data sense amplifiers (e.g., DSA) 223 and error correction circuitry 203 in an analogous manner. The DSA 223 can also be referred to as sensing circuitry and/or sense amplifiers. In other examples (e.g., the example of FIG. 5), each bank has its own DSA and ECC circuitry but may share the PU 202. Having separate DSAs 223 and ECC circuitries 203 allows each of the banks 230 to provide data to the shared PU 202 independent of the other banks. A shared PU 202 can function at twice the speed as compared to a PU that is not shared. For example, if a read latency of the banks 230 is 5 ns, then a first bank 230-0 can provide data to the PU 202 at the start of the 5 ns and a second bank 230-8 can provide data to the PU 202 halfway through the 5 ns (e.g., 2.5 ns).

Each of the PUs 202 can be coupled to or include a MUX 231-2. The MUX 231-2 enables the PU 202 to be implemented with less MAC units while retaining the same throughput. For example, if each of the PUs 202 is implemented with sixteen MAC units instead of thirty-two MAC units, then the PUs 202 can be implemented with sixty-four MAC units using the MUXs 231-2 instead of one hundred twenty-eight MAC units. The MUXs 231-2 allow for the PUs 202 to be implemented with at least half the MAC units than PUs implemented without the MUXs. If 4:1 MUXs are utilized in the PUs 202, the PUs 202 can be implemented with eight MAC units instead of one hundred twenty-eight MAC units used to implement PUs 202 without MUXs.

Implementing the PUs 202 using fewer MAC units can decrease the cost of implementing the PUs 202. Implementing the PUs 202 using fewer MAC units can also decrease the size of the die that includes the PUs 202.

Data can be provided from the banks 230 to the DSAs 223 via a MUX 231-1. For example, the bank 230-0 and the bank 230-8 can provide data to the MUX 231-1. The bank 230-0 can provide 256 bits in a first duration of time and the bank 230-8 can provide 256 bits to the MUX 231-1 in a second duration of time.

Given that a shared DSA 223 is implemented, the DSA 223 may not be configured to receive 512 bits of data. The MUX 231-1 can provide the first 256 bits to the DSAs 223 in a first duration of time. The MUX 231-1 can provide the second 256 bits to the DSAs 223 in a second duration of time. The DSAs 223 can utilize half of the die space as compared to the die space utilized by a first DSA of a first bank and a second DSA of a second bank.

During the first duration of time the DSAs 223 can provide the amplified first data to the ECC 203. During the second duration of time the DSAs 223 can provide the amplified second data to the ECC 203.

The ECC 203 can perform a plurality of operation on the first data during a third duration of time and can provide a first output to the MUX 231-2. The ECC 203 can perform a plurality of operations on the second data during a fourth duration of time and can provide a second output to the MUX 231-2. The ECC 203 can provide a first number of bits (e.g., 128 bits) and a second number of bits (e.g., 128 bits) to the MUX 231-2. The ECC 203 can utilize half the die space as compared to ECCs that are not shared.

In fifth duration of time, the MUX 231-2 can provide the first number of bits and the second number of bits to the PU 202. For example, the MUX 231-2 can provide the first number of bits to the PU 202 in a first portion of the fifth duration of time. The MUX 231-2 can provide the second number of bits to the PU 202 in a second portion of the fifth duration of time. The first portion can be a first half of the fifth duration of time and the second portion can be a second half of the fifth duration of time. Although the examples described herein are provided utilizing a first half of a duration of time and a second half of a duration of time. The examples can be applied to portions of a duration of time and are not limited to half portions of the duration of time.

The PU 202 can function at half the speed as compared to the speed at which a first PU of a first bank and a second PU of a second bank function. The PU 202 can utilize half of the die space as compared to the die space utilized by a first PU of a first bank and a second PU of a second bank. The DSAs 223 and the ECCs 203 can utilize half the space as compared to the space utilized by the DSAs and ECC coupled to a first bank and the DSAs and ECC coupled to a second bank. The DSAs 223 and the ECCs 203 can also function at half the speed.

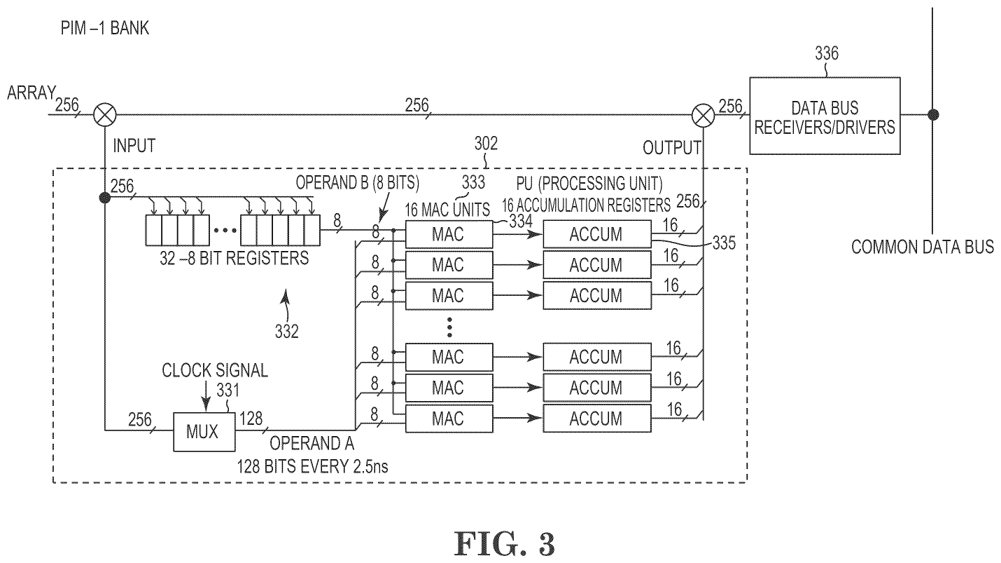

FIG. 3 is a block diagram of a processing unit 302 (e.g., the PU 102 of FIG. 1 and/or the PU 202 of FIG. 2) including a MUX 331 (e.g., a 2:1 MUX) in accordance with a number of embodiments of the present disclosure. Although the MUX 331 is shown as being part of the PU 302, the MUX 331 can also be implemented external to the PU 302. For example, the MU 331 can be implemented between the PU 202 and the ECC 203 of FIG. 2. The PU 302 can include the MUX 331 (e.g., 2:1 MUX), a shift register 332, and MAC units 333. The PU 302 can receive data from banks (e.g., memory array), as previously described herein. The PU 302 can also receive data from the data bus 336. The data bus 336 can include receivers and/or drivers. The data bus 336 can couple the PU 302 to the interface of the memory device (e.g., via a common data bus). The data bus 336 can be used to provide data to the PU 302 from a host coupled to the memory device and/or from the banks of the memory device.

In the example of FIG. 3 the PU 302 can receive data from the banks and/or from the host via the data bus 336 once per read latency period. For example, a bank can provide data to the PU 302 once every 5 ns. Although the read latency is described as being 5 ns, other latencies can be utilized to describe a duration of time used to provide data to the PU 302. For example, data can be provided to the PU 302 every 10 ns or 2.5 ns.

An operand B can be provided to the PU 302 and stored in the registers 332. Operand B can comprise two hundred fifty-six bits, which can represent, for example, thirty-two data values. The thirty-two data values can be stored in the registers 332. For example, the shift registers 332 can include thirty-two eight bit registers. Each of the registers of the registers 332 can store eight bits (e.g., a data value). The operand B can be provided from a bank (e.g., DRAM array) of the memory device.

The registers 332 can be shift registers 332. The shift registers 332 can provide the same data value (e.g., eight bits) to each of the MAC units 333. Once a data value (e.g., eight bits) has been provided to the MAC units 333, the shift registers 332 can shift a position of the data values such that the next data value (e.g., the next eight bits) is available and the data value previously provided is last in line. The shift registers 332 can then provide the next data value to each of the MAC units 333. In such a fashion, the shift registers 332 can rotate through the thirty-two data values (e.g., rotate through the two hundred fifty-six bits), providing one data value (e.g., eight bits) at a time to the MAC units. 333.

The operand A can be provided from the I/O lines via the data bus 336. The operand A can also comprise thirty-two data values (e.g., two hundred fifty-six bits) that can remain active in the data bus 336 for the duration of the 5 ns. Although the examples described herein are provided in terms of data being provided in two hundred fifty-six bit chunks, other data size chunks can be provided to the PU 302. For example, the data bus 336 can carry sixteen data values (e.g., one hundred twenty-eight bits) or sixty-four data values (e.g., five hundred twelve bits).

The operand A can be provided to the MUX 331. The MUX 331 can be implemented internal to the PU 302 and between the MAC units 333 and the data bus 336. The MUX 331 can be implemented as an interface to the PU 302.

The MUX 331 can be a 2:1 MUX that provides a first half of the data values during a first half of the read latency and provides the second half of the data values during a second half of the read latency. For example, the MUX 331 can provide the first sixteen data values (e.g., one hundred twenty-eight bits) to the MAC units 333 during the first 2.5 ns of the read latency. The MUX 331 can provide the second sixteen data values (e.g., one hundred twenty-eight bits) to the MAC units during the second 2.5 ns of the read latency. The MUX 331 can receive a clock signal that enables the MUX 331 to provide data based on the partitioned read latency (e.g., every 2.5 ns). The term partitioned read latency can reference that the read latency is divided to describe different intervals than those conveyed by the read latency.

The MUX 331 can provide different data values to each of the MAC units 333. For example, given that there are sixteen MAC units 333 in the example of FIG. 3, the MUX 331 can provide sixteen data values (e.g., one hundred twenty-eight bits) to the MAC units 333 such that each of the MAC units 333 receives a different data value (e.g., eight bits) from the sixteen data values.

Each MAC unit 333 can include a multiplicator 334 and an accumulator 335 (also referred to as accumulation registers 335). Each of the MAC units 333 can receive a data value from the operand B and a data value from the operand A. The multiplicator 334 of each respective MAC unit 333 can perform a plurality of multiplication operations utilizing the received data values from the operand B and the operand A. The output of each respective multiplicator 334 can be provided to a different respective accumulator 335. Each accumulator 335 can sum the respective output of the multiplicators 334 and the previous outputs of the multiplicators 334. Each of the accumulators 335 can include thirty two-bit registers.

The example of FIG. 3 shows sixteen multiplicators 334 and sixteen accumulators 335. Reducing the quantity of the MAC units 333 can also reduce the quantity of multiplicators 334 and the quantity of accumulators 335 implemented in the PU 302. Reducing the quantity of multiplicators 334 and the quantity of accumulators 335 can reduce the size and/or cost of the PU 302.

The data in the accumulators 335 can be read to obtain the output of the MAC units 333. The interface between the accumulators 335 and the data bus 336 can also be updated to accommodate the fewer MAC units 333 implemented in view of the implementation of the MUX 331 in the PU 302. For example, each of the accumulators 335 can output two data values (e.g., sixteen bits) at time. Given that there are sixteen accumulators 335, the output of the PU 302 can be thirty-two data values (e.g., two hundred and twenty-six bits). Each of the accumulators 335 can be coupled to the data bus 336 via sixteen lines. In contrast, in previous approaches in which thirty-two accumulators were implemented, each of the accumulators 335 would be coupled to the data bus 336 using eight lines.

The implementation of the MUX 331 allows for fewer MAC units 333 to be implemented which increases the quantity of lines coupling the MAC units 333 to the data bus 336. The increase in the quantity of lines coupling the MAC units 333 to the data bus 336 allows for the same throughput to be established between the data bus 336 and the MAC units 333 as compared to implementations where the MUX 331 is not implemented.

Once the MAC units 333 conclude performing a plurality of operations on the sixteen data values (e.g. one hundred twenty-eight bits) provided by the MUX 331, the MUX 331 can provide the second sixteen data values (e.g., the second one hundred twenty-eight bits) to the MAC units 333, and operations (e.g., multiplication operations) can be performed on the second sixteen data values in ana analogous manner. The MAC units 333 can consistently be utilized in the read latency (e.g., 5 ns) because sixteen data values (e.g., one hundred twenty-eight bits) are provided to the MAC units 333 every 2.5 ns.

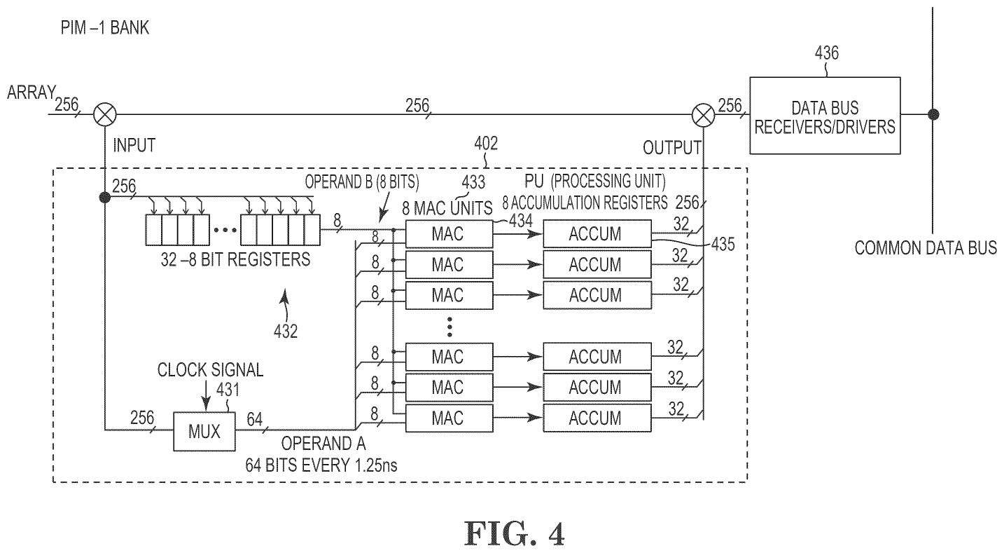

FIG. 4 is a block diagram of a processing unit including a 4:1 MUX 431 in accordance with a number of embodiments of the present disclosure. The PU 402 can include the MUX 331 (e.g., 4:1 MUX), shift register 432, and MAC units 433. As described, the MUX 431, although shown as being part of the PU 402, can be implemented externally to the PU 402. The PU 402 can receive data from the banks (e.g., memory array). The PU 402 can also receive data from the data bus 436. The data bus 436 can include receivers and/or drivers. The data bus 436 can couple the PU 402 to the interface of the memory device. The data bus 436 can be used to provide data to the PU 402 from the host coupled to the memory device and/or from the banks of the memory device.

In the example of FIG. 4 the PU 402 can receive data from the banks and/or from the host via the data bus 436 once every read latency. For example, a bank can provide data to the PU 402 once every 5 ns.

An operand B can be provided to the PU 402 and stored in the registers 432. Operand B can be composed of thirty-two data values. The thirty-two data values can be stored in the registers 432. For example, the shift registers 432 can include thirty-two eight bit registers. Each of the registers of the registers 432 can store a data value (e.g., eight bits). The operand B can be provided from a bank (e.g., DRAM array) of the memory device.

The registers 432 can be shift registers 432. The shift registers 432 can provide the same data value to each of the MAC units 433. Once a data value has been provided to the MAC units 433, the shift registers 432 can shift a position of the data values such that the next data value is available and the data value previously provided is last in line. The shift registers 432 can then provide the next eight bits to each of the MAC units 433. In such a fashion, the shift registers 432 can rotate through thirty-two data values, providing a data value at a time to the MAC units. 433.

The operand A can be provided from the I/O lines via the data bus 436. In examples where multiple banks are coupled to the PU 402, the operand A can be provided to the PU 402 from a first bank and operand B can be provided to the PU 402 from a second bank. For example, each of the banks can provide data to the PU 402 once every read latency. However, the banks can be staggered in providing data to the PU 402 such that the PU 402 receives data every 2.5 ns.

The operand A can also comprise thirty-two data values that can remain active in the data bus 436 for the duration of the read latency. The read latency can be 5 ns if the operand A is being received from the host or a bank. The read latency can be 2.5 ns if the operand A is being received from a bank and the operand B is received from a different bank.

Although the examples described herein are provided in terms of data being provided in two hundred fifty-six chunks (e.g., providing thirty-two data values), other size chunks can be provided to the PU 402. For example, the data bus 436 can carry sixteen data values (e.g., one hundred twenty-eight bits) or sixty-four data values (e.g., five hundred twelve bits).

The operand A can be provided to the MUX 431. The MUX 431 can be implemented internal to the PU 402 and between the MAC units 433 and the data bus 436. The MUX 431 can be implemented as an interface to the PU 402.

The MUX 431 can be a 4:1 MUX that provides a first portion of the data values during a first portion the read latency, a second portion of the data values during a second portion of the read latency, a third portion of the data values during a third portion of the read latency, and a fourth portion of the data values during a fourth portion of the read latency. The data values can include the data values of the operand A. For example, the MUX 431 can provide the first eight data values (e.g., the first sixty-four bits) to the MAC units 433 during the first 1.25 ns of the read latency. The MUX 431 can provide the second eight data values (e.g., the second sixty-four bits) to the MAC units during the second 1.25 ns of the read latency. The MUX 431 can provide the third eight data values (e.g., the third sixty-four bits) to the MAC units during the third 1.25 ns of the read latency. The MUX 431 can provide the fourth data values (e.g., the fourth sixty-four bits) to the MAC units during the fourth 1.25 ns of the read latency. The MUX 431 can receive a clock signal that enables the MUX 431 to provide data values based on the partitioned read latency (e.g., every 1.25 ns).

The MUX 431 can provide a different data value to each of the MAC units 433. For example, given that there are eight MAC units 433 in the example of FIG. 4, the MUX 431 can provide eight data values (e.g., sixty-four bits) to the MAC units 433, at the same time, such that each of the MAC units 433 receives a different data value from the eight data values.

The MAC units 433 can include a multiplicator 434 and an accumulator 435 also referred to as accumulation registers 435. Each of the MAC units 433 can receive a data value from the operand B and a different data value from the operand A. The multiplicators 434 can perform a plurality of multiplication operations using the data values from the operand B and the operand A. The output of the multiplicators 434 can be provided to the accumulators 435. The accumulators 435 can sum the output of the multiplicators 434 and the previous outputs of the multiplicators 334. The accumulators 335 can each include thirty two-bit registers. The example of FIG. 4 shows eight multiplicators 434 and eight accumulators 435. Reducing the quantity of the MAC units 433 can also reduce the quantity of multiplicators 434 and the quantity of accumulators 435 implemented in the PU 402. Reducing the quantity of multiplicators 434 and the quantity of accumulators 435 can reduce the expense of implementing the PU 402.

The accumulators 435 can be read to obtain the output of the MAC units 433. The interface between the accumulators 435 and the data bus 436 can also be updated to accommodate that fewer MAC units 433 are implemented in view of the implementation of the MUX 431 (e.g., 4:1 MUX) in the PU 402. For example, each of the accumulators 435 can output thirty-two bits at time. Given that there are eight accumulators 435, the output of the PU 402 can be two hundred and twenty-six bits. Each of the accumulators 435 can be coupled to the data bus 436 via thirty-two lines. In previous approaches where thirty-two accumulators were implemented each of the accumulators 435 are coupled to the data bus 436 using eight bits.

The implementation of the MUX 431 allows for fewer MAC units 433 to be implemented which increases the quantity of lines coupling the MAC units 4533 to the data bus 436 to retain the same throughput of two hundred fifty-six bits. The increase in the quantity of lines coupling the MAC units 433 to the data bus 436 allows for a same throughput to be established between the data bus 436 and the MAC units 433 as compared to implementations where the MUX 431 is not implemented.

Once the MAC units 433 conclude performing a plurality of operations on the eight data values provided by the MUX 431, the MUX 431 can provide the second eight data values to the MAC units 433, etc. The MAC units 433 can consistently be utilized in the read latency (e.g., 5 ns) because eight data values are provided to the MAC units 433 every 1.25 ns.

In various examples, the operand A can be provided from a first bank and a second bank coupled to the PU 402. Given that the read latency of the first bank is 5 ns and that the read latency of the second bank is also 5 ns. The first bank and the second bank can be configured to provide data at staggered intervals. For example, the first bank can provide data in the first 2.5 ns while the second bank provides data in the second 2.5 ns.

The MUX internal to the bank 402 can be configured as a 2:1 MUX. The MUX can receive the first operand A from the first bank and can provide a first half of the data during the first 1.25 ns of the read latency. The MUX can provide the second half of the first operand A in the second 1.25 ns. The MUX can receive a second operand A from a different bank and can provide a first half of the second operand A during the third 1.25 ns of the read latency. The MUX can provide the second half of the second operand A during the fourth 1.25 ns of the read latency. The sixteen MAC units can receive the operand A and the operand B from the MUX as similarly shown in FIG. 3.

FIG. 5 is a block diagram of a memory device 520 including a MUX 531 coupled to multiple ECC 503-1, 503-2 and a PU 502 in accordance with a number of embodiments of the present disclosure. FIG. 5 includes the banks 530-0, 530-1, 530-2, 530-3, 530-4, 530-5, 530-6, 530-7, 530-8, 530-9, 530-10, 530-11, 530-12, 530-13, 530-14, 530-15 which can be referred to collectively as banks 530. The banks 530 are analogous to the banks 230 of FIG. 2.

The banks 530 can be grouped into bank groups 521. For example, the banks 530-0, 530-1, 530-8, 530-9 can be grouped into a first bank group (e.g., bank group 0). The banks 530-2, 530-3, 530-10, 530-11 can be grouped into a second bank group (e.g., bank group 1). The banks 530-4, 530-5, 530-12, 530-13 can be grouped into a third bank group (e.g., bank group 2). The banks 530-6, 530-7, 530-14, 530-15 can be grouped into a fourth bank group (e.g., bank group 3).

The banks of each respective bank group can be organized into pairs that share a PU 502. For example, the banks 530-0, 530-8 of bank group 0 share a first PU (e.g., the PU 202). The banks 530-1, 530-9 of bank group 0 share a second PU. The banks 530-2, 530-10 of bank group 1 share a third PU. The banks 530-3, 530-11 of bank group 1 share a fourth PU. The banks 530-4, 530-12 of bank group 2 share a fifth PU. The banks 530-5, 530-13 of bank group 2 share a sixth PU. The banks 530-6, 530-14 of bank group 3 share a seventh PU. The banks 530-7, 530-15 of bank group 3 share an eighth PU.

The example of FIG. 5 also shows that the bank pairs do not share DSAs (e.g., DSAs 523-1, 523-2) or ECC circuitry (e.g., ECC circuitry 503-1, 503-2). In the example of FIG. 5, each bank has its own DSA and ECC circuitry but may share the PU. Having separate DSAs 523-1, 523-2 and ECC circuitries 503-1, 503-2 allows each of the banks 530 to provide data to the shared PU 502 independent of the other banks.

In the example of FIG. 5, a first bank can provide data (e.g., 256 bits) to the DSA 523-1 and a second bank can provide data (e.g., 256 bits) to the DSA 523-2 concurrently. The DSAs 523-1, 523-2 can amplify the sensed data and can provide the amplified data to the ECC circuitries 503-1, 503-2 in a first duration of time. For example, the DSA 523-1 can provide amplified data to the ECC circuitry 503-1 in the first duration of time. The DSA 523-2 can also provide amplified data to the ECC circuitry 503-2 in the first duration of time.

The ECC circuitries 523-1, 523-2 can perform a plurality of operations and can provide an output of the plurality of operation to the MUX 531 in a second duration of time. For example, the ECC circuitry 523-1 can perform a plurality of operation using data (e.g., 256 bits) received from the DSA 523-1 in the second duration of time to generate a first output. The ECC circuitry 523-2 can perform a plurality of operation using data (e.g., 256 bits) received from the DSA 523-2 in the second duration of time to generate a second output. The ECC circuitries 523-1, 523-2 can provide the first output and the second output in the second duration of time to the MUX 531. The ECC circuitries 523-1, 523-2 can provide the first output and the second output concurrently to the MUX 531.

There are no space saving in the implementation of separate DSAs 523 and ECC circuitries 503 for each bank. The use of the MUX 531 to couple a single PU 502 to the ECC circuitries 503-1, 503-2 allows for space savings as compared to implementing a separate PU for each bank are implemented.

The MUX 531 can provide the first output (e.g., 256 bits) to the PU 502 in a first half of a third duration of time and the second output (e.g., 256 bits) to the PU 502 in a second half of the third duration of time. The PU 502 can perform a plurality of operation on the received first output, which becomes a first input to the PU 502, in the first half of the third duration of time. The PU 502 can perform a plurality of operation on the received second output, which becomes a second input to the PU 502, in the second half of the third duration of time.

The PU 502 is shared between two banks and can function at twice the speed as compared to a PU that is implemented for a single bank. The PU 502, that is shared between two banks, can also utilize half the die space as compared to the die space utilized by a first PU of a first bank and a second PU of a second bank.

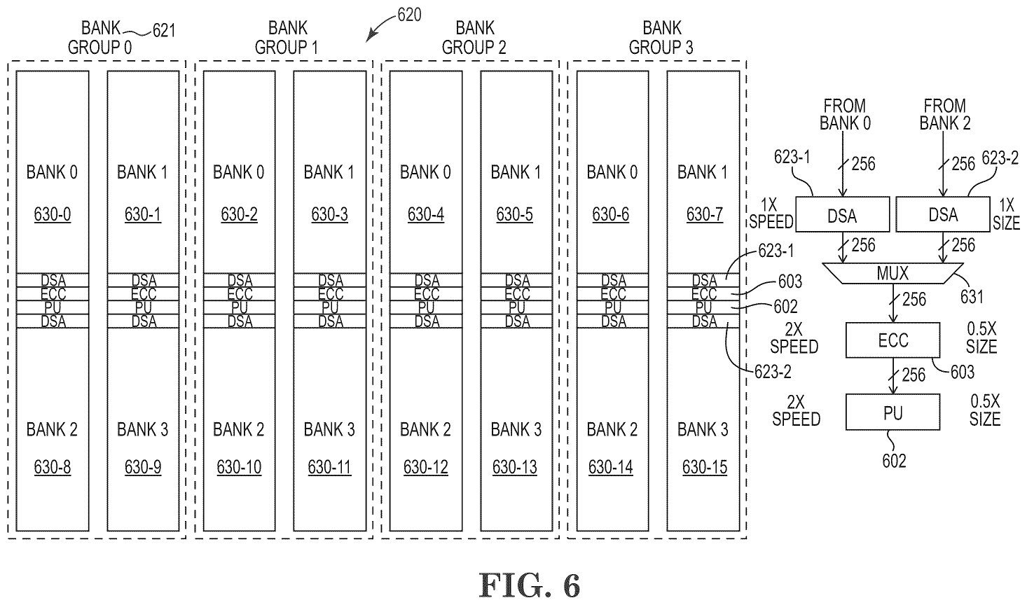

FIG. 6 is a block diagram of a memory device 620 including a MUX 631 coupled to multiple DSAs 623-1, 623-2 and an ECC circuitry 603 in accordance with a number of embodiments of the present disclosure. FIG. 6 includes the banks 630-0, 630-1, 630-2, 630-3, 630-4, 630-5, 630-6, 630-7, 630-8, 630-9, 630-10, 630-11, 630-12, 630-13, 630-14, 630-15 which can be referred to collectively as banks 630. The banks 630 are analogous to the banks 230 of FIG. 2 and the banks 530 of FIG. 5.

The banks 630 can be grouped into bank groups 621. For example, the banks 630-0, 630-1, 630-8, 630-9 can be grouped into a first bank group (e.g., bank group 0). The banks 630-2, 630-3, 630-10, 630-11 can be grouped into a second bank group (e.g., bank group 1). The banks 630-4, 630-5, 630-12, 630-13 can be grouped into a third bank group (e.g., bank group 2). The banks 630-6, 630-7, 630-14, 630-15 can be grouped into a fourth bank group (e.g., bank group 3).

The banks of each respective bank group can be organized into pairs that share a PU 602. For example, the banks 630-0, 630-8 of bank group 0 share a first PU (e.g., the PU 502). The banks 630-1, 630-9 of bank group 0 share a second PU. The banks 630-2, 630-10 of bank group 1 share a third PU. The banks 630-3, 630-11 of bank group 1 share a fourth PU. The banks 630-4, 630-12 of bank group 2 share a fifth PU. The banks 630-5, 630-13 of bank group 2 share a sixth PU. The banks 630-6, 630-14 of bank group 3 share a seventh PU. The banks 630-7, 630-15 of bank group 3 share an eighth PU.

The example of FIG. 6 also shows that although the bank pairs do not share a DSA 623-1, 623-2 the bank pairs share the ECC circuitry 603. In the example of FIG. 6, each bank has its own DSA but shares an ECC circuitry 603 and the PU 602 with a different bank.

In the example of FIG. 6, a first bank can provide data (e.g., 256 bits) to the DSA 523-1 and a second bank can provide data (e.g., 256 bits) to the DSA 523-2. The DSAs 523-1, 523-2 can amplify the sensed data and can provide the amplified data to the MUX 631 in a first duration of time.

The MUX 631 can provide the amplified data to the ECC circuitry 603 in a first half of a second duration of time and a second half of the second duration of time. For instance, the MUX 631 can provide first amplified data, received from the DSA 623-1, in the first half of the second duration of time. The MUX 631 can provide second amplified data, received from the DSA 623-2, in the second half of the second duration of time.

The ECC circuitry 602 can perform a plurality of operations on the first amplified data in the first half of the second duration of time to generate a first output. The ECC circuitry 602 can perform a plurality of operations on the second amplified data in the second half of the second duration of time to generate a second output. The ECC circuitry 602 can occupy half the die space as compared to the die space occupied by a first ECC circuitry of a first bank and a second ECC circuitry of a second bank. The ECC circuitry 602 can also function at twice the speed as compared to the speed at which a first ECC circuitry of a first bank and a second ECC circuitry of a second bank function. The ECC circuitry 602 can provide the first output (e.g., 256 bits) to the PU 602 in the first half of the second duration of time and the second output (e.g., 256 bits) to the PU 602 in the second half of the second duration of time.

The PU 602 can perform a first plurality of operations on the first output, received as a first input, in a first half of a third duration of time. The PU 602 can perform the first plurality of operations on the second output, received as second input, in the second half of the third duration of time. The PU 602 can utilize half of the die space as compared to the die space utilized by a first PU of a first bank and a second PU of a second bank. The PU 602 can also function at twice the speed as compared to the speed at which the first PU of the first bank and the second PU of the second bank function.

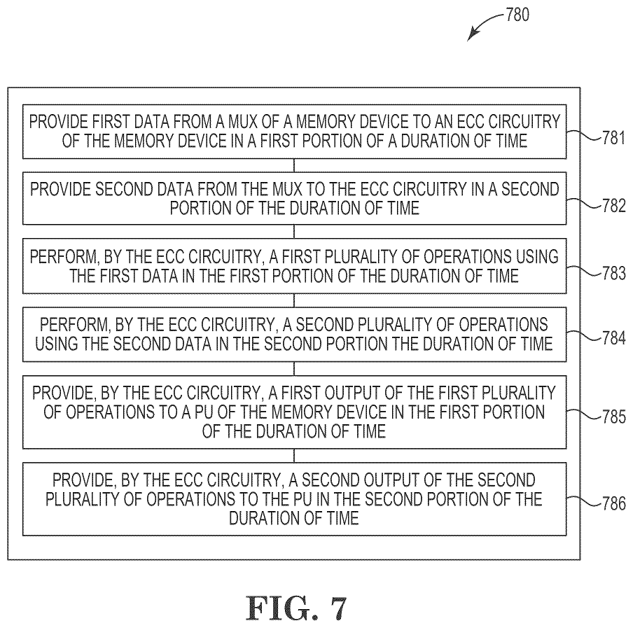

FIG. 7 illustrates an example flow diagram of a method 780 for implementing (e.g., operating) a multiplexor in a processing unit of memory in accordance with a number of embodiments of the present disclosure. The method can be performed by a memory device of a computing system, such as, for instance, memory device 120 of computing system 100 previously described in connection with FIG. 1.

At 781, a MUX (e.g., the MUX 631 of FIG. 6), of a memory device (e.g., the memory device 620 of FIG. 6), can provide first data to an ECC circuitry (e.g., the ECC circuitry 603 of FIG. 6) of the memory device in a first portion of a duration of time. The ECC circuitry can be shared between a first bank and a second bank that comprise a bank pair of a bank group of the memory device.

At 782, the MUX can provide second data to the ECC circuitry in a second portion of the duration of time. The ECC circuitry can function at twice the speed such that for each duration of time the ECC circuitry can process two sets of data. The ECC circuitry can utilize half the die space as compared to ECC circuitries that are not shared by multiple banks.

At 783, the ECC circuitry can perform a first plurality of operations using the first data in a first portion of the duration of time. At 784, the ECC circuitry can perform a second plurality of operations using the second data in the second portion of the duration of time. At 785, the ECC circuitry can provide a first output of the first plurality of operations to a PU (e.g., the PU 602 of FIG. 6) of the memory device in the first portion of the duration of time. At 786, the ECC circuitry can provide a second output of the second plurality of operations to the PU in the second portion of the duration of time.

The memory device can also include a first DSA coupled to the MUX. The first DSA can provide the first data to the MUX in a second duration of time. The second duration of time can occur before the first duration of time. A first bank can provide the first duration of time to the first DSA in the second duration of time.

The memory device can also include a second DSA coupled to the MUX. The second DSA can provide the second data to the MUX in the second duration of time. A second bank of the memory device can provide the second data to the second DSA in the second duration of time.

In various examples, a first ECC circuitry can receive first data from a first bank of a memory device. A second ECC circuitry can receive second data from a second bank of the memory device. The first ECC circuitry can correspond to a first bank and the second ECC circuitry can correspond to a second bank of the memory device.

The memory device can also include a MUX. The MUX can receive the first data from the first ECC circuitry and the second data from the second ECC circuitry. The MUX can provide the first data in a first portion of a duration of time. The MUX can provide the second data in a second portion of the duration of time.

The memory device can also include a PU. The PU can perform a first plurality of multiplication operations utilizing the first data provided by the MUX during the first portion of the duration of time. The PU can also perform a second plurality of multiplication operations utilizing the second data provided by the MUX during the second portion of the duration of time.

The first bank and the second bank can be in a bank group of the memory device. A first DSA can provide the first data to the first ECC circuitry in a different duration of time. The first DSA can receive the first data from the first bank. A second DSA can provide the second data to the second ECC circuitry in the different duration of time. The first DSA and the second DSA can provide the first data and the second data concurrently. The second DSA can receive the second data from the second bank.

The PU can include a plurality of MAC units. The MAC units can perform the first plurality of multiplication operations utilizing the first data provided by the MUX during the first portion of the duration of time. The MAC units can also perform the second plurality of multiplication operations utilizing the second data provided by the MUX during the second portion of the duration of time.

After providing the first data and the second data, the MUX can receive additional data in a next duration of time. The next duration of time can occur after the duration of time.

In various instances, first DSAs can receive first data from a first bank of a memory device. Second DSAs can receive second data from a second bank of the memory device. A MUX can receive the first data from the first DSA and the second data from the second DSA. The MUX can provide the first data in a first portion of a duration of time and the second data in a second portion of the duration of time. ECC circuitry can perform a first plurality of operations utilizing the first data provided by the MUX during the first portion of the duration of time and can perform a second plurality of operations utilizing the second data provided by the MUX during the second portion of the duration of time.

The ECC circuitry can, responsive to performing the first plurality of operations, generate a first output data in the first portion of the duration of time. The ECC circuitry can also provide the first output data to a PU in the first portion of the duration of time. The PU can perform a first plurality of multiplication operations in a first portion of a different duration of time.

The ECC circuitry can, responsive to performing the second plurality of operations, generate a second output data in the second portion of the duration of time. The ECC circuitry can provide the second output data to a PU in the second portion of the duration of time. The PU can perform a second plurality of multiplication operations in a second portion of a different duration of time.

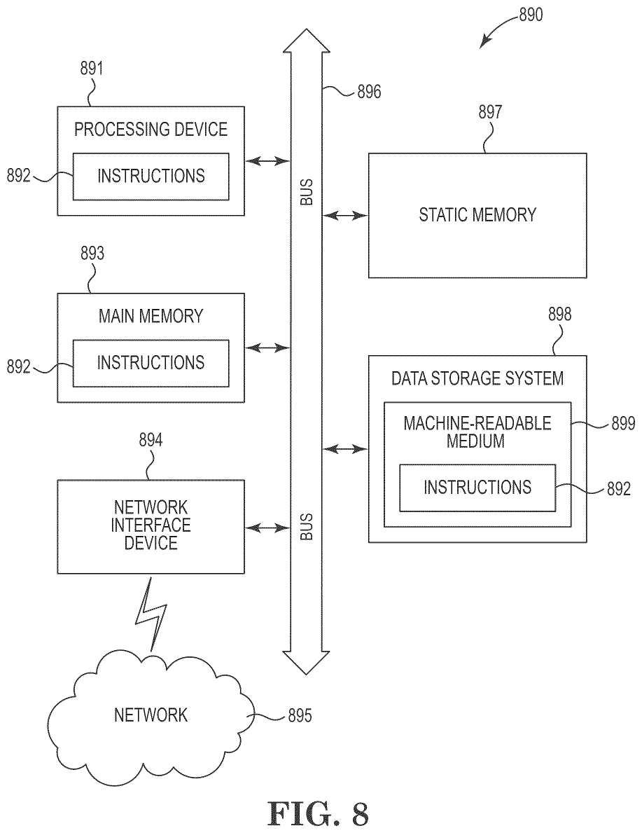

FIG. 8 illustrates an example machine of a computer system 890 within which a set of instructions, for causing the machine to perform any one or more of the methodologies discussed herein, can be executed. In some embodiments, the computer system 890 can correspond to a host system (e.g., the host 110 of FIG. 1) that includes, is coupled to, or utilizes a memory device (e.g., the memory device 120 of FIG. 1) or can be used to perform the operations of the PU (e.g., the PU 102 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 890 includes a processing device 891, a main memory 893 (e.g., read-only memory (ROM), flash memory, dynamic random access memory (DRAM) such as synchronous DRAM (SDRAM) or Rambus DRAM (RDRAM), etc.), a static memory 897 (e.g., flash memory, static random access memory (SRAM), etc.), and a data storage system 898, which communicate with each other via a bus 896.

Processing device 891 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 891 can also be one or more special-purpose processing devices such as an application specific integrated circuit (ASIC), a field programmable gate array (FPGA), a digital signal processor (DSP), network processor, or the like. The processing device 891 is configured to execute instructions 892 for performing the operations and steps discussed herein. The computer system 890 can further include a network interface device 894 to communicate over the network 895.

The data storage system 898 can include a machine-readable storage medium 899 (also known as a computer-readable medium) on which is stored one or more sets of instructions 892 or software embodying any one or more of the methodologies or functions described herein. The instructions 892 can also reside, completely or at least partially, within the main memory 893 and/or within the processing device 891 during execution thereof by the computer system 890, the main memory 893 and the processing device 891 also constituting machine-readable storage media.

In one embodiment, the instructions 892 include instructions to implement functionality corresponding to the PU 102 of FIG. 1. While the machine-readable storage medium 899 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Although specific embodiments have been illustrated and described herein, those of ordinary skill in the art will appreciate that an arrangement calculated to achieve the same results can be substituted for the specific embodiments shown. This disclosure is intended to cover adaptations or variations of various embodiments of the present disclosure. It is to be understood that the above description has been made in an illustrative fashion, and not a restrictive one. Combinations of the above embodiments, and other embodiments not specifically described herein will be apparent to those of skill in the art upon reviewing the above description. The scope of the various embodiments of the present disclosure includes other applications in which the above structures and methods are used. Therefore, the scope of various embodiments of the present disclosure should be determined with reference to the appended claims, along with the full range of equivalents to which such claims are entitled.

In the foregoing Detailed Description, various features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a first error correction code (ECC) circuitry configured to receive first data from a first bank of a memory device;
a second ECC circuitry configured to receive second data from a second bank of the memory device;
a multiplexor (MUX) coupled to the first ECC circuitry and the second ECC circuitry and configured to:
receive the first data from the first ECC circuitry and the second data from the second ECC circuitry;
provide the first data in a first portion of a duration of time;
provide the second data in a second portion of the duration of time; and
a processing unit (PU) coupled to the MUX and configured to:
perform a first plurality of multiplication operations utilizing the first data provided by the MUX during the first portion of the duration of time; and
perform a second plurality of multiplication operations utilizing the second data provided by the MUX during the second portion of the duration of time.

2. The apparatus of claim 1, wherein the first bank and the second bank are within a same bank group of the memory device.

3. The apparatus of claim 1, further comprising a first data sense amplifier (DSA) configured to provide the first data to the first ECC circuitry in a different duration of time.

4. The apparatus of claim 3, wherein the first DSA is configured to receive the first data from the first bank.

5. The apparatus of claim 3, further comprising a second DSA configured to provide the second data to the second ECC circuitry in the different duration of time.

6. The apparatus of claim 5, wherein the first portion of the duration of time is a first half of the duration of time, wherein the second portion of the duration of time is a second half of the duration of time, and wherein the second DSA is configured to receive the second data from the second bank.

7. The apparatus of claim 1, wherein the PU comprises a plurality of multiply-accumulate (MAC) units configured to:
perform the first plurality of multiplication operations utilizing the first data provided by the MUX during the first portion of the duration of time; and
perform the second plurality of multiplication operations utilizing the second data provided by the MUX during the second portion of the duration of time.

8. The apparatus of claim 1, wherein the MUX is further configured to receive additional data after the duration of time.

9. An apparatus, comprising:
first data sense amplifiers (DSAs) configured to receive first data from a first bank of a memory device;
second DSAs configured to receive second data from a second bank of the memory device;
a multiplexor (MUX) configured to:
receive the first data from the first DSAs and the second data from the second DSAs;
provide the first data in a first portion of a duration of time;
provide the second data in a second portion of the duration of time; and
an error correction code (ECC) circuitry configured to:
perform a first plurality of operations utilizing the first data provided by the MUX during the first portion of the duration of time; and
perform a second plurality of operations utilizing the second data provided by the MUX during the second portion of the duration of time.

10. The apparatus of claim 9, wherein the ECC circuitry is further configured to, responsive to performing the first plurality of operations, generate a first output data in the first portion of the duration of time, wherein the first portion of the duration of time is a first half of the duration of time.

11. The apparatus of claim 10, wherein the ECC circuitry is further configured to provide the first output data to a processing unit (PU) in the first half of the duration of time.

12. The apparatus of claim 11, further comprising the PU configured to perform a first plurality of multiplication operations in a first half of a different duration of time.

13. The apparatus of claim 9, wherein the ECC circuitry is further configured to, responsive to performing the second plurality of operations, generate a second output data in the second portion of the duration of time, wherein the second portion of the duration of time is a second half of the duration of time.

14. The apparatus of claim 13, wherein the ECC circuitry is further configured to provide the second output data to a processing unit (PU) in the second half of the duration of time.

15. The apparatus of claim 14, further comprising the PU configured to perform a second plurality of multiplication operations in a second half of a different duration of time.

16. A method, comprising:
providing first data from a multiplexor (MUX) of a memory device to an error correction code (ECC) circuitry of the memory device in a first portion of a duration of time;
providing second data from the MUX to the ECC circuitry in a second portion of the duration of time;
performing, by the ECC circuitry, a first plurality of operations using the first data in the first portion of the duration of time;
performing, by the ECC circuitry, a second plurality of operations using the second data in the second portion of the duration of time;
providing, by the ECC circuitry, a first output of the first plurality of operations to a processing unit (PU) of the memory device in the first portion of the duration of time; and
providing, by the ECC circuitry, a second output of the second plurality of operations to the PU in the second portion of the duration of time.

17. The method of claim 16, further comprising providing the first data from a first data sense amplifier (DSA) to the MUX in a second duration of time.

18. The method of claim 17, further comprising providing the first data from a first bank to the first DSA in the second duration of time, wherein the first portion of the duration of time is a first half of the duration of time and the second portion of the duration of time is a second half of the duration of time.

19. The method of claim 16, further comprising providing the second data from a second data sense amplifier (DSA) to the MUX in a second duration of time.

20. The method of claim 19, further comprising providing the second data from a second bank to the second DSA in the second duration of time.
